(19) United States
(12) Patent Application Publication
(10) Pub. No.: US 2015/0138701 A1
(43) Pub. Date: May 21, 2015

(54) PORTABLE DEVICE, SYSTEM, AND METHOD

(71) Applicant: Vandana SIKKA, Los Altos Hills, CA (US)

(72) Inventor: Vandana SIKKA, Los Altos Hills, CA (US)

(21) Appl. No.: 14/548,277

(22) Filed: Nov. 19, 2014

Related U.S. Application Data
(60) Provisional application No. 61/906,407, filed on Nov. 19, 2013.

(51) Int. Cl. H05K 5/02; G06F 3/044; G06F 3/045; G06F 1/16

(52) U.S. Cl. CPC H05K 5/02; G06F 1/1626; G06F 1/1643; G06F 1/1658; G06F 3/044; G06F 3/045
USPC 361/679.3; 349/12

(57) ABSTRACT

Aspects of the present invention describe a computing device having a housing or casing in and/or on which a touch sensitive screen is coupled. The housing or casing is made of a flexible material, so that it can be partially bent or even rolled. For example, the casing is made of a bendable polymer or pressure treated, waterproof wood. The casing of the computing device has beveled edges for ease of grip.

### CROSS-REFERENCE TO RELATED APPLICATIONS

This application claims priority to U.S. Provisional Patent Application Ser. No. 61/906,407, filed on Nov. 19, 2013, entitled “PORTABLE DEVICE, SYSTEM, AND METHOD,” the entirety of which is herein incorporated by reference in its entirety.

### COPYRIGHTS

A portion of the disclosure of this patent document contains material which is subject to copyright protection. The copyright owner has no objection to the facsimile reproduction by anyone of the patent document or the patent disclosure, as it appears in the Patent and Trademark Office patent files or records, but otherwise reserves all copyrights whatsoever.

### FIELD OF INVENTION

The present invention relates generally to the field of portable electronic devices, and more specifically, to a device, system, and method for providing a housing, casing, or device for a portable electronic device or other machine/material.

### RELATED INFORMATION

Conventional portable devices are designed to be symmetrical, with square or rounded edges, and are typically made of a plastic material. However, these devices are often difficult and/or inconvenient to pick up and hold. Accordingly, there is a need in the art for a more user-friendly and protective casing.

### SUMMARY

Embodiments of the present invention provide for an apparatus or device, system, and method for providing a housing, casing, or other device for holding or presenting a portable electronic device or other machine or material.

Embodiments of the present invention provide for a handheld computing device, method and system including a rectangular casing, wherein at least two sides of the casing are beveled and the casing is made from a flexible material; and a touch sensitive screen. In embodiments, the short sides of the casing are beveled inward towards the bottom of the device. In embodiments, the long sides of the casing are beveled inward towards the bottom of the device. In embodiments, the short sides of the casing are beveled inward towards the top of the device. In embodiments, the long sides of the casing are beveled inward towards the top of the device. In embodiments, all four sides of the casing are beveled. In embodiments, the at least two sides of the casing are beveled by 2 mm. In embodiments, the flexible material is a bendable polymer. In embodiments, the flexible material is wood based. In embodiments, the touch sensitive screen is a capacitive screen for receiving input. In embodiments, the touch sensitive screen is a resistive screen for receiving input. In embodiments, the touch sensitive screen is both a capacitive screen and a resistive screen for receiving input.

Embodiments of the present invention provide for a computer tablet system, method, and device including: a display screen; and a rectangular housing, wherein the housing is made from a flexible material; wherein the screen is coupled to housing. In embodiments, at least two sides of the housing are beveled. In embodiments, at least two sides of the housing are beveled straight inward toward the top of the computer tablet system, beveled straight inward toward the bottom of the computer tablet system, rounded inward toward the top of the computer tablet system, or rounded inward toward the bottom of the computer tablet system. In embodiments, corners of the housing are square, rounded, or beveled. In embodiments, the housing is made from a material selected from at least one of: plastic, hardgrade plastic, rubber, metal, tin, carbon fiber, titanium, wood, processed aluminum, bendable polymer, and pressure treated wood. In embodiments, the housing is at least one of: smooth, rough, lightly variegated, heavily variegated, wavy, and has indentations for finger grips. In embodiments, the housing is coupled to a screen via at least one of a hinge, a snap, a clip, a band, an adhesive, a removably-attached adhesive, and a magnetic apparatus.

### BRIEF DESCRIPTION OF THE DRAWINGS

The foregoing and other aspects of various embodiments of the present invention will be apparent through examination of the following detailed description thereof in conjunction with the accompanying drawing figures in which similar reference numbers are used to indicate functionally similar elements.

FIG. 1A is an elevated view illustrating device dimensions according to an example embodiment of the present invention.

FIG. 1B is a side view illustrating device dimensions according to an example embodiment of the present invention.

FIG. 2 illustrates dimensions for a device according to an example embodiment of the present invention.

FIG. 3 illustrates dimensions for a device according to an example embodiment of the present invention.

FIG. 4 illustrates dimensions for a device according to an example embodiment of the present invention.

FIG. 5 is an elevated view illustrating dimensions for two devices according to an example embodiment of the present invention.

FIG. 6 illustrates beveling for a device according to an example embodiment of the present invention.

FIG. 7 illustrates beveling for a device according to an example embodiment of the present invention.

FIG. 8 illustrates beveling for a device according to an example embodiment of the present invention.

FIG. 9 illustrates beveling for a pair of devices according to an example embodiment of the present invention.

FIG. 10 illustrates a device with a display according to an example embodiment of the present invention.

FIG. 11 illustrates dimensions for a device according to an example embodiment of the present invention.

FIG. 12 illustrates dimensions for a device according to an example embodiment of the present invention.

FIG. 13A illustrates a device according to an example embodiment of the present invention.

FIG. 13B illustrates a device according to an example embodiment of the present invention.

FIG. 14A illustrates a side view of a device according to an example embodiment of the present invention.

FIG. 14B illustrates a side view of a device according to an example embodiment of the present invention.

FIG. 14C illustrates a side view of a device according to an example embodiment of the present invention.

FIG. 14D illustrates a side view of a device according to an example embodiment of the present invention.

FIG. 15A illustrates a side view of a corner or side of a device according to an example embodiment of the present invention.

FIG. 15B illustrates a side view of a corner or side of a device according to an example embodiment of the present invention.

FIG. 15C illustrates a side view of a corner or side of a device according to an example embodiment of the present invention.

FIG. 15D illustrates a side view of a corner or side of a device according to an example embodiment of the present invention.

FIG. 15E illustrates a side view of a corner or side of a device according to an example embodiment of the present invention.

FIG. 15F illustrates a side view of a corner or side of a device according to an example embodiment of the present invention.

FIG. 15G illustrates a side view of a corner or side of a device according to an example embodiment of the present invention.

FIG. 15H illustrates a side view of a corner or side of a device according to an example embodiment of the present invention.

FIG. 15I illustrates a side view of a corner or side of a device according to an example embodiment of the present invention.

### DETAILED DESCRIPTION

Aspects of the present invention include a computing device having a housing or casing on which a screen is coupled. The housing (or casing) is made of any of a variety of and/or combination of different materials, including, for example, at least one of plastic, hardgrade plastic, rubber, metal, tin, carbon fiber, titanium, wood, processed aluminum, etc. For example, the housing is made of a material that conducts heat. For example, the housing is made of a material that acts as a cooling agent. The housing is manufactured as a single piece of material, or as a hollowed piece of material, or as a compilation of pieces of material.

In an embodiment, the casing is flexible, so that it can be partially bent or even rolled. For example, the casing is made of a polymer or pressure treated, waterproof wood.

In an embodiment, the housing is rectangular-shaped or square-shaped, with edges which angle down to another rectangular shape or square shape. Each of the edges are at least one of beveled, rounded, and sharp. In an embodiment, the edges display a fanciful design. In an embodiment, the edges angle down at a specific angle, depending upon the intended user. For example, for a child-aged user, the edges angle down at a 90 degree angle (i.e., straight down) or at a high angle between 46 and 90 degrees. For example, for an adult-aged user, the edges angle down at a lesser angle such as from 0 to 45 degrees.

In an embodiment, the housing is coupled to a screen. For example, the screen is a thin portable computing device. For example, the screen is connected to a computing device. For example, the coupling of the housing to the screen is by mechanical apparatus. A mechanical apparatus can include at least one of: a hinge, a snap, a clip, and a band, etc. For example, the coupling of the housing to the screen is by a magnetic apparatus. For example the magnetic coupling is attached to each of the housing and the screen, and the magnetic force between the two magnetic couplings. For example, the coupling of the housing to the screen is by an adhesive. The adhesive can include at least one of: a permanent adhesive, a removably attachable adhesive, an organic adhesive, a combination of material friction and an adhesive, etc.

In an embodiment, the bottom part of the housing includes a material attached to the housing which allows for better gripping. For example, a rubber-like or grabby material is situated across all or part of the bottom portion of the housing.

According to an embodiment of the invention, a thin portable computing device is composed of a semi-flexible and maneuverable material. In an embodiment, the computing device includes at least one of a metal, plastic, wooden or other known material casing. For example, some portion or the entire casing forming the back and sides of the device includes carbon fiber. Some portions of the device casing include rubber or other grippable material. For example, the edges and/or corners are padded. In an embodiment, the casing has a variety of colors and designs. For example, the casing may be solid black, white, slate gray, or any desired color or is composed of a design such as a striped or checkerboard pattern or a leopard print.

In an embodiment, the computing device has beveled edges for ease of grip and be lightweight for convenient transport. In an embodiment, the computing device is of any size. For example, the computing device is rectangular in shape with approximate dimensions 9 inches×12 inches, 10 inches×16 inches, 8 inches×14 inches, or 9 inches×13.5 inches. For example, the computing device is approximately ½ inch thick or less.

Other shapes can also be used. For example, the device can be circular, square, star, or some other polygon/shape.

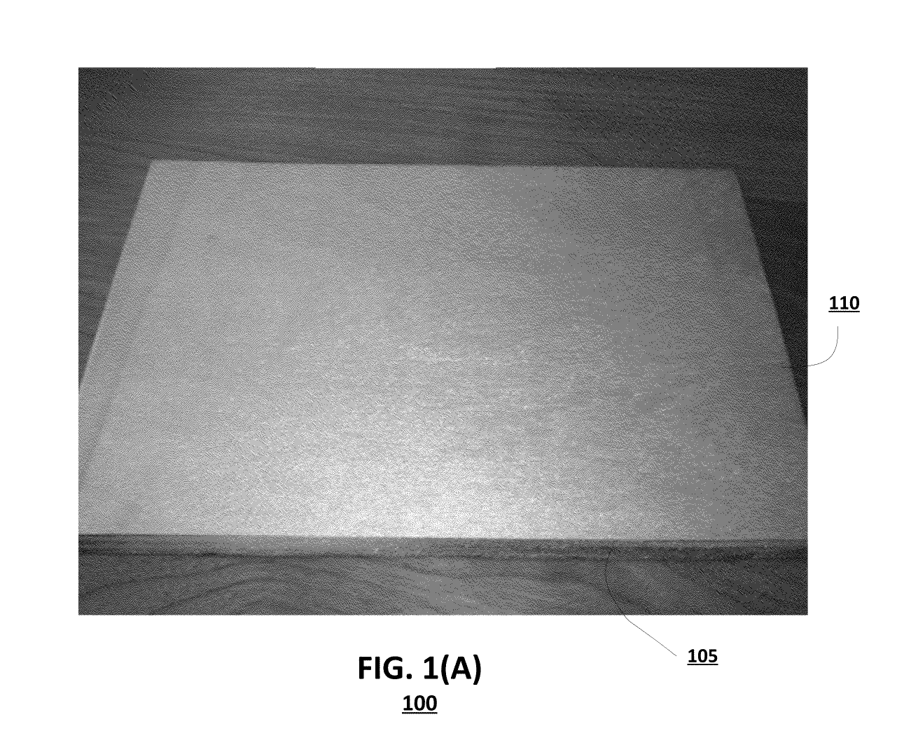

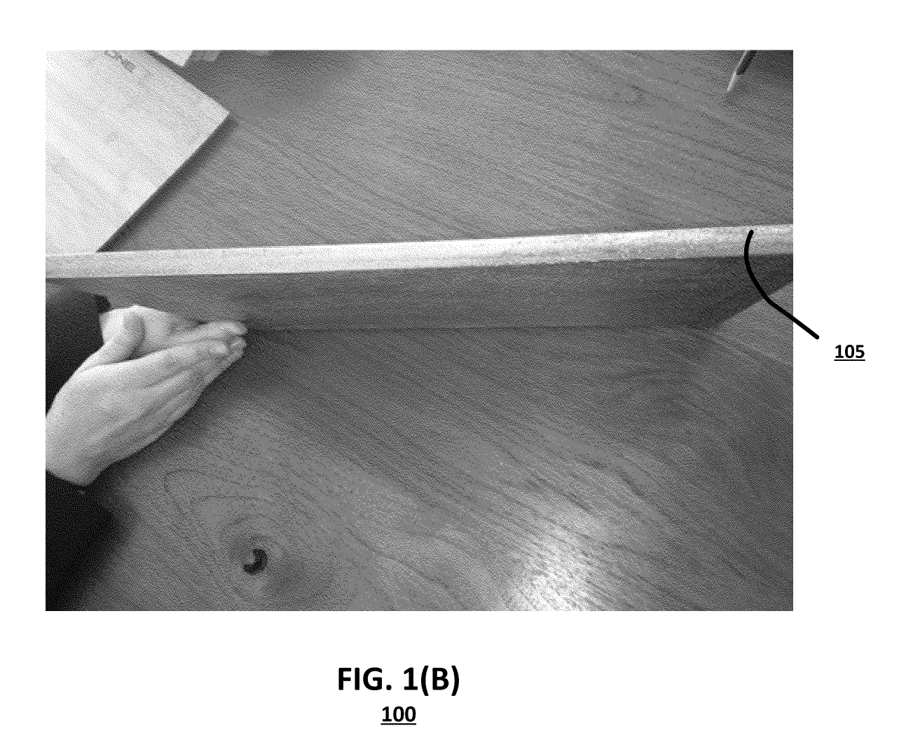

FIG. 1 illustrates exemplary dimensions for a device with the edges beveled such that all the edges are cut inward towards the bottom. FIG. 1A is an elevated view illustrating exemplary device dimensions and FIG. 1B is a side view illustrating exemplary device dimensions. According to an embodiment, the device is approximately 0.19 inches thick or less.

As shown in FIG. 1A, a device 100 is shaped with the edges on the short side 105 beveled inward towards the bottom. As shown in FIG. 1B, the long side 110 of the device 100 is beveled towards the bottom. The edges can be beveled at different angles, for example, to provide for a better grip, depending upon the intended user. The corners and edges can be rounded or straight. The corners of the device can be cut in a diagonal, for example, at a 45 degree angle to the sides of the device.

In an embodiment, the edges are slanted inwards towards the top.

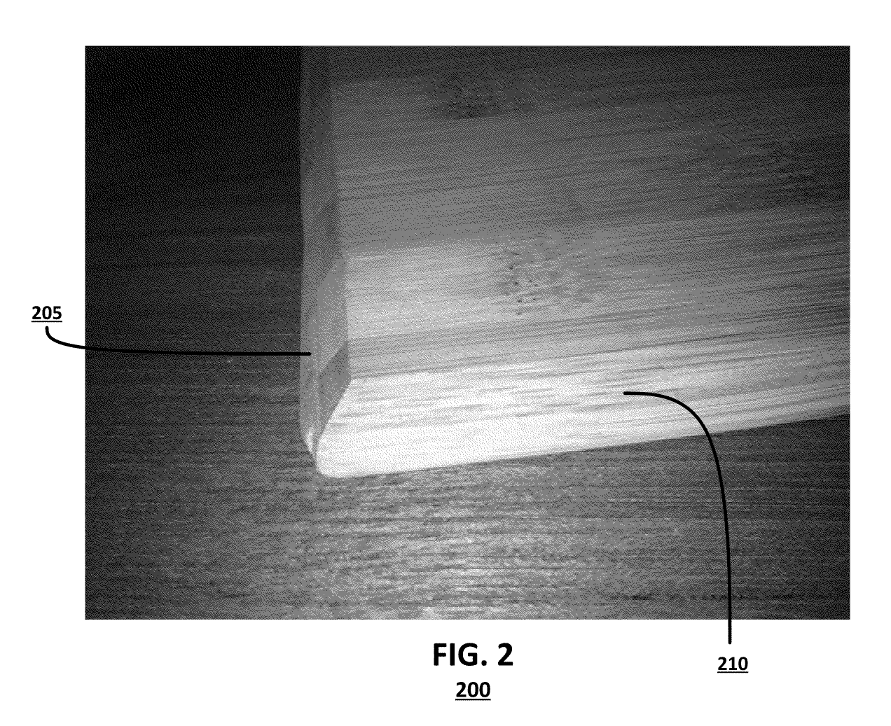

FIG. 2 illustrates exemplary dimensions for a device 200 with the edges beveled such that the edges on the longer sides 210 are slanted inward towards the bottom of the device and the edges on the shorter sides 205 are slanted inward towards the top of the device. In an embodiment, the sides of the device are beveled such that the beveling is approximately 2 mm inward.

In an embodiment, the longer sides may be slanted inward towards the top of the device and the shorted sides slanted inward towards the bottom of the device. This provides for a convenient or ergonomic way to grip the device regardless of which side is facing up.

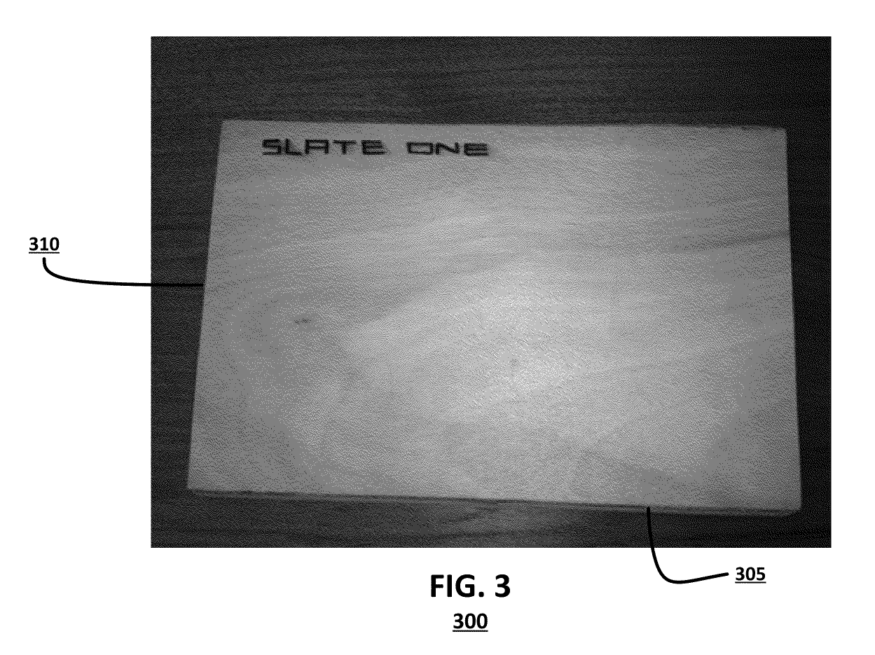

FIG. 3 illustrates exemplary dimensions for a device 300. As shown in

FIG. 3, the device is 9 inches×12 inches. According to an embodiment, the bottom of the device is 9 inches×12 inches and due to the beveling of all the sides inward towards the bottom of the device, the top of the device is slightly larger than the bottom surface (e.g., 9.25 inches×12.25 inches or less).

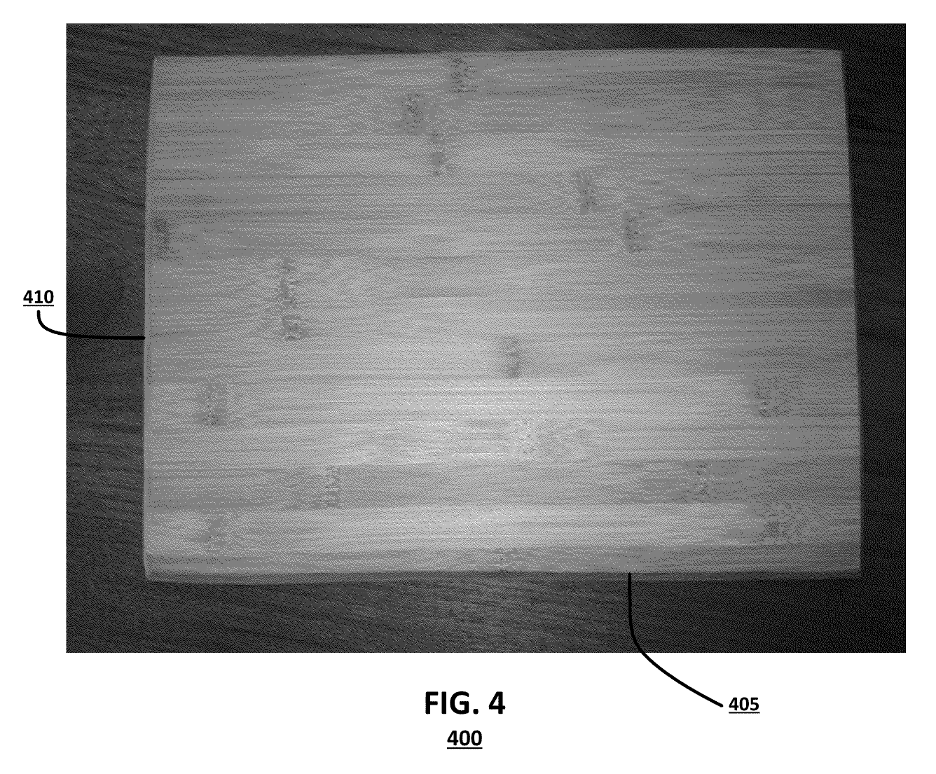

FIG. 4 illustrates exemplary dimensions for a device 400. As shown in FIG. 4, the device is 10 inches×16 inches.

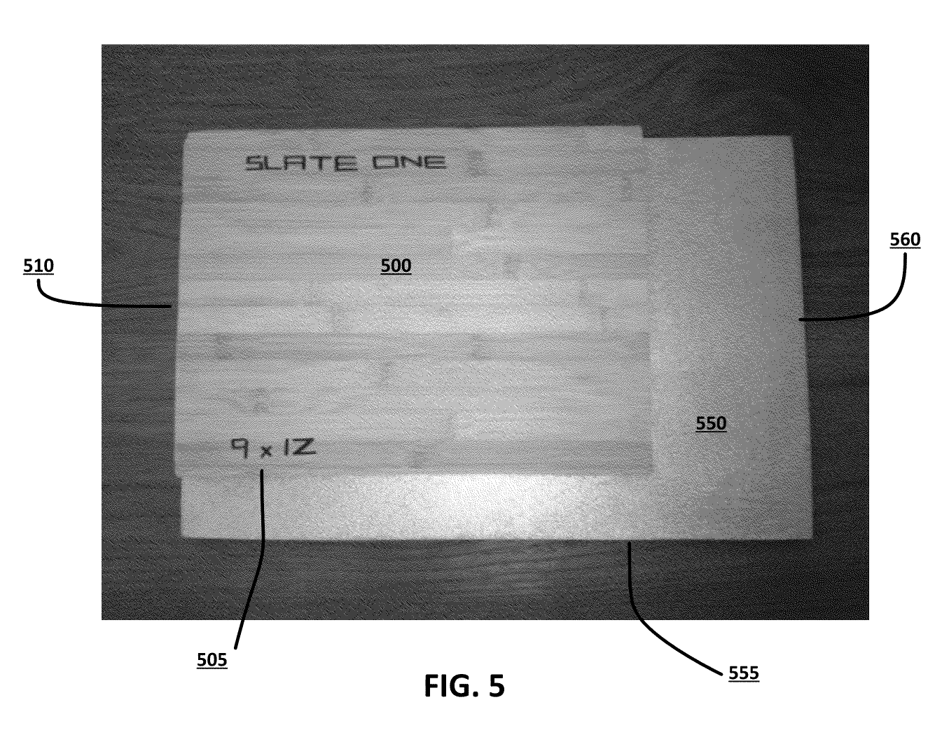

FIG. 5 shows an elevated view illustrating exemplary dimensions for two devices 500, 550. As shown in FIG. 5, a first device 500 has the dimensions of 9 inches on the short side 510 and 12 inches on the long side 505. A second device 550 has the dimensions of 10 inches on the short side 560 and 16 inches on the long side 555.

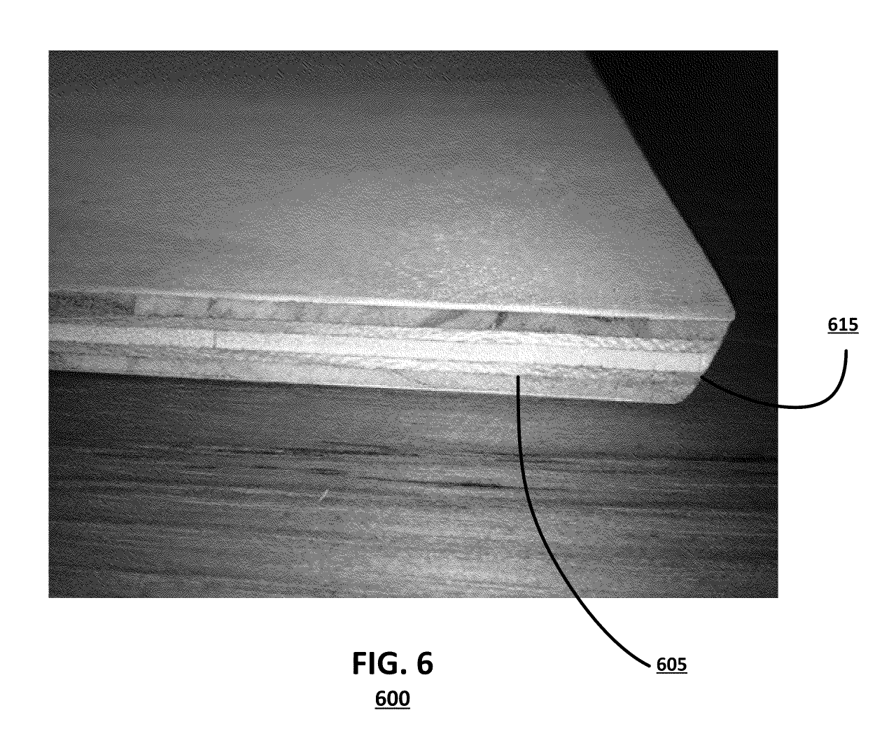

FIG. 6 illustrates exemplary beveling for a device 600. As shown in FIG. 6, the edges on the side 605 are slanted inward towards the bottom of the device 600. Additionally, the corner 615 of the device 600 is rounded. According to an embodiment, the rounding will be slight, such as 2 percent or less of the length of the side 605 is rounded.

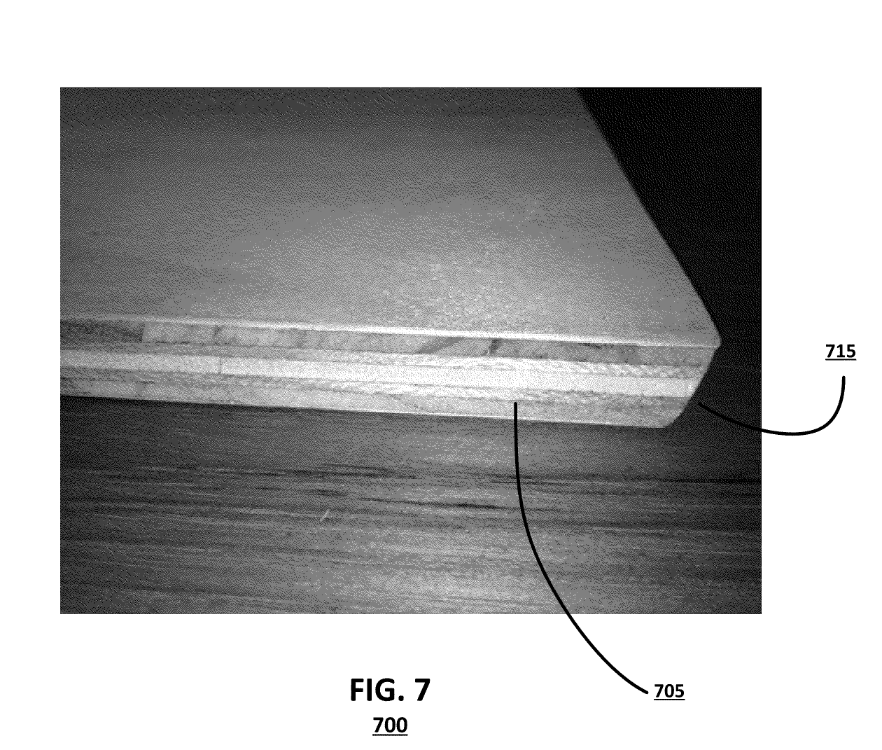

FIG. 7 illustrates exemplary beveling for a device 700. As shown in FIG. 7, the edges on the side 705 are slanted inward towards the bottom of the device 700 and the corner 715 of the device 700 is rounded.

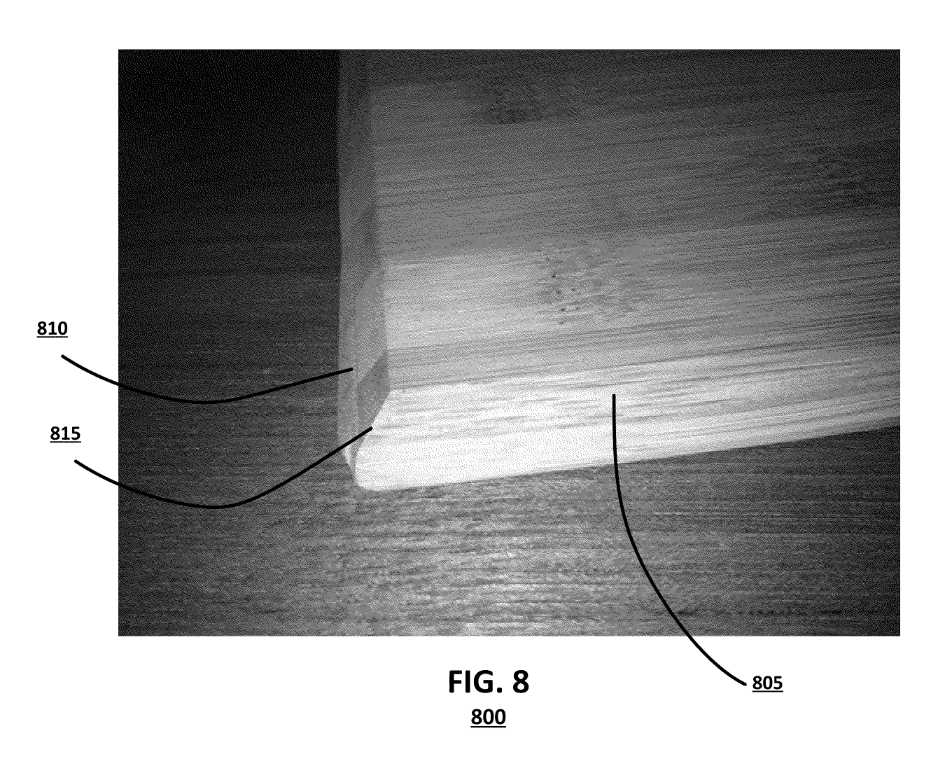

FIG. 8 illustrates exemplary beveling for a device 800. As shown in FIG. 8, the edges on the sides 805 and 810 are slanted inward towards the top of the device 800. According to an embodiment, and as shown in FIG. 8, the corner 815 of the device 800 is not rounded.

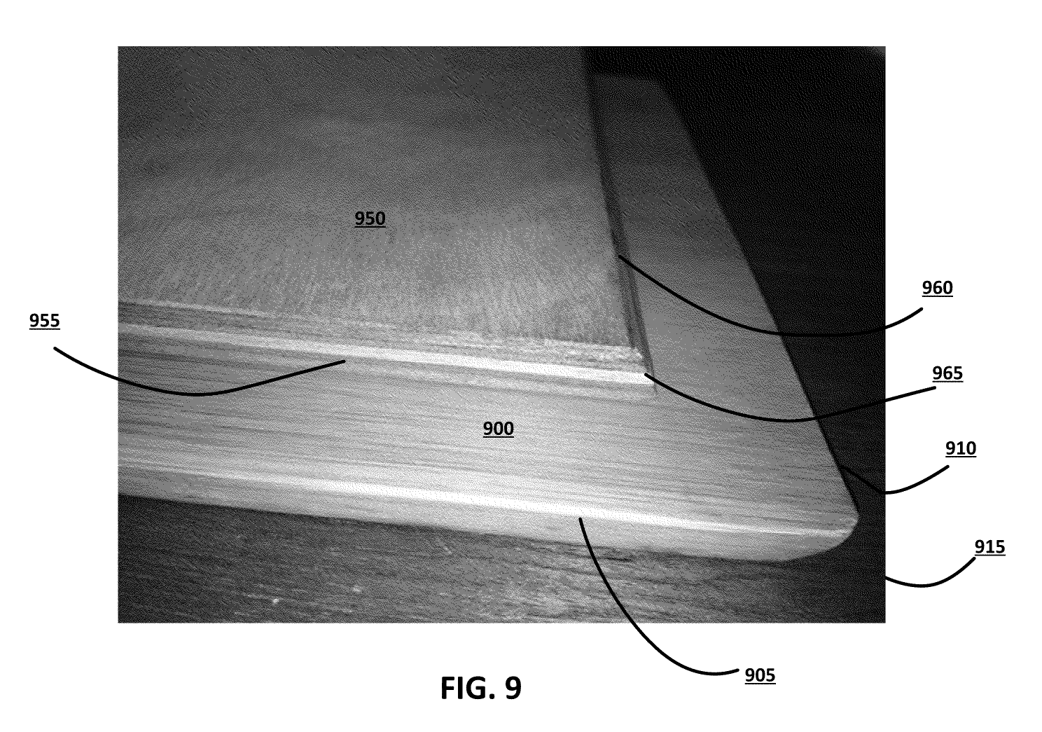

FIG. 9 illustrates exemplary beveling for a pair of devices 900, 950. As shown in FIG. 9, the edges on the sides 905, 910 of a first device 900 are slanted inward towards the bottom of the device 900. In an embodiment, the corner 915 of the device 900 is rounded. In an embodiment, the edges on the sides 955, 960 of a second device 950 are slanted inward towards the top of the device 950 and the corner 965 of the device 950 is not rounded.

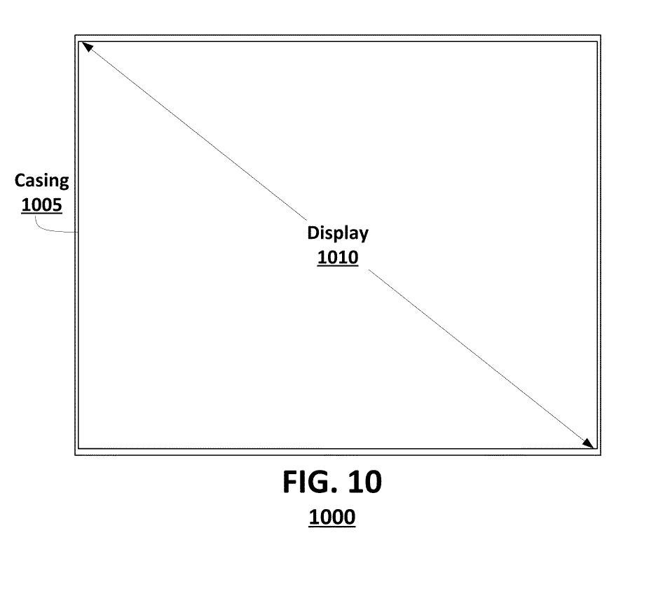

In embodiments, the device has a display sensitive to touch, whether capacitive or resistive, or a combination of both, such that input can be received via the display itself. FIG. 10 illustrates an exemplary device with a display. In an embodiment, as shown in FIG. 10, the screen of the display is not nearly as large as the device itself, with only a small portion of the casing surrounding the screen on top and on the sides. Other widths for the edge portions of the casing can be implemented.

The computing device may have multiple input modes, including, for example, a mode that receives input via touch and a mode that receives input via a stylus or pen device associated with the computing device. The computing device can switch to a stylus input mode upon removal of the stylus device from an attached location of the computing device. The display additionally can have a high resolution to allow for extensive zoom functionality.

According to an embodiment, the device has an off balance center of gravity such that the center of mass will be in at the grip or hold points of the device.

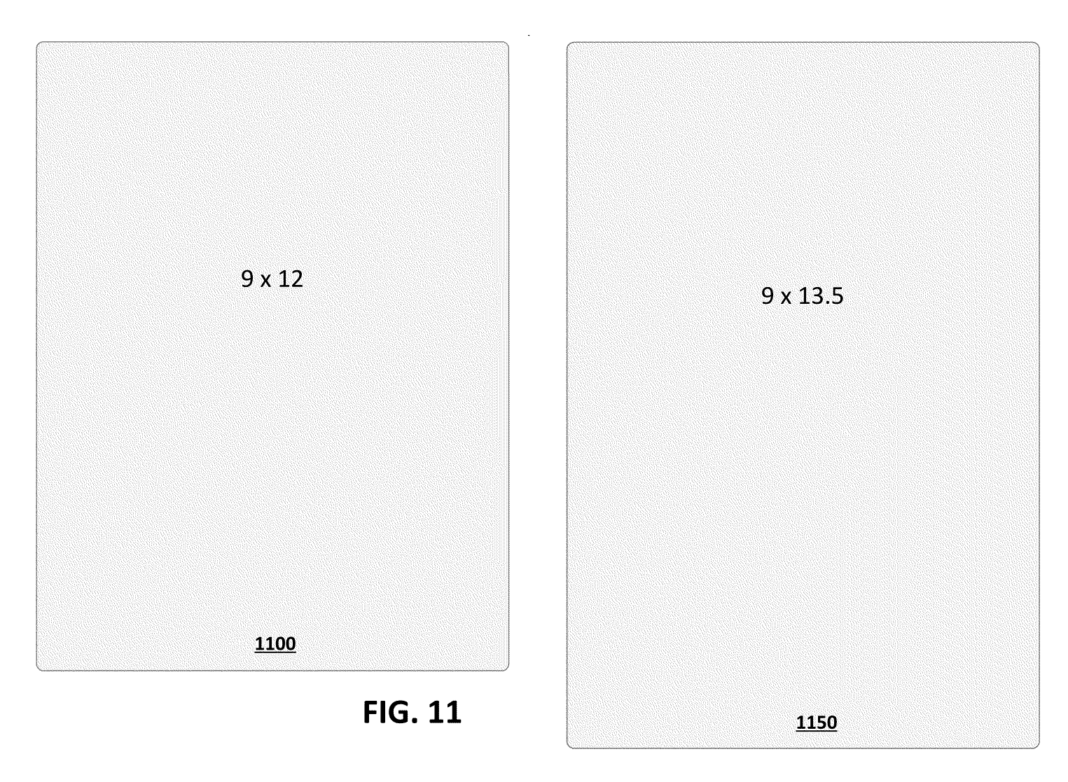

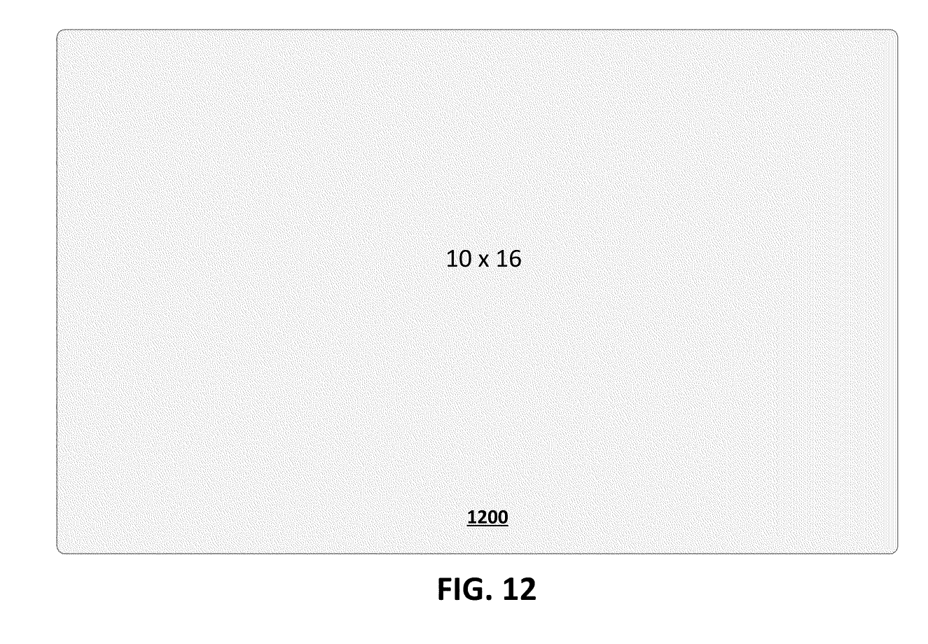

FIG. 11 shows example embodiments of different sized housings 1100, 1150 of 9×12 and 9×13.5. FIG. 12 shows an example embodiment of a different sized housing 1200 of 10×16. These dimensions provide ratio of length and width, and can be inverted (width and length).

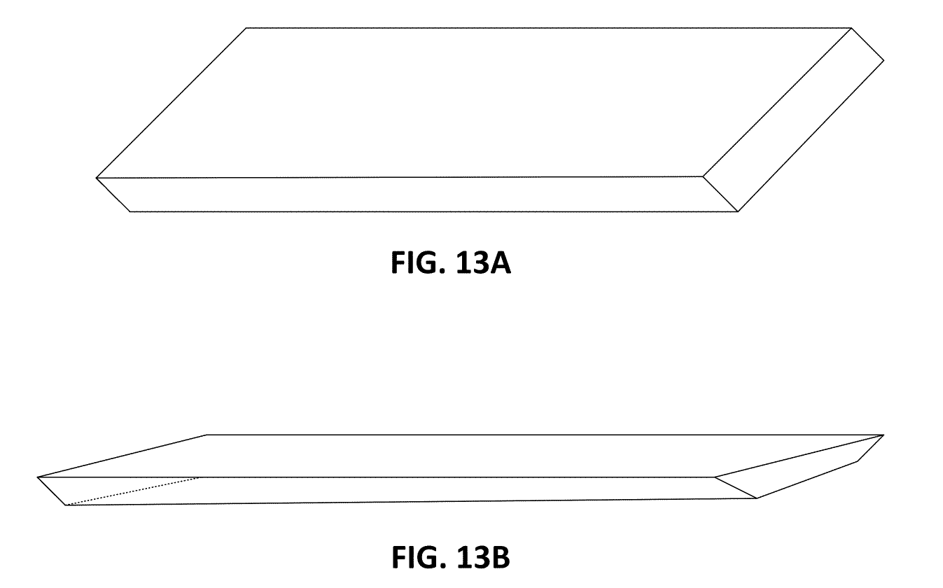

FIG. 13A shows an example system where the tablet covers the entire surface of the housing.

FIG. 13B shows an example system where the bottom portion of the housing extends inward to a smaller surface area.

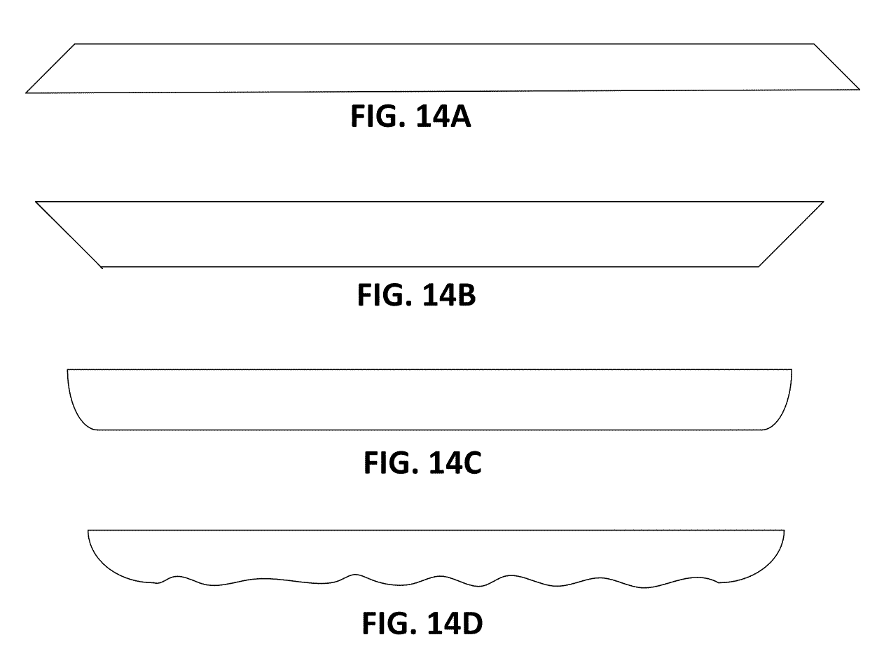

FIGS. 14A-14B-14C-14D show a side view of example embodiments of the present invention. FIG. 14A shows an example housing where the edges extend outward from the upper portion of the housing. FIG. 14B shows an example housing where the edges extend inward from the upper portion of the housing. FIG. 14C shows an example housing where the edges extend inward from the upper portion and are beveled. FIG. 14D shows an example housing where the edges are beveled and the bottom portion is at least one of variegated, smooth, and provide grippy edges or positions for fingers to hold.

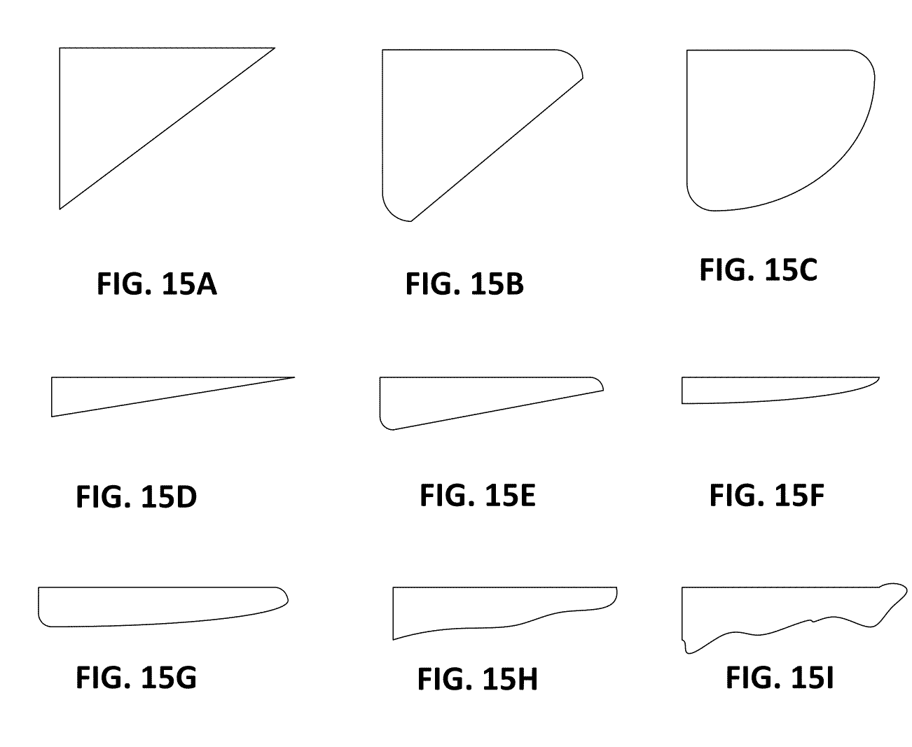

FIGS. 15A-15B-15C-15D-15E-15F-15G-15H-15I each show a side view of an example corner and/or side according to an example embodiment of the present invention. FIG. 15A shows a flat, angled region ending in sharp edges at the top and bottom of the corner or side.

Embodiments of the present invention provide for a housing having a very slight rounding of the edges. For example the rounding of the edges and/or sides is 2% or less in angle from top to bottom. Embodiments of the present invention provide for a housing having a base surface which is wider than the top surface. For example, the top surface has a width of about 9 inches and the bottom surface has a width of about 9.25 inches. For example, the top surface has a width of about 9 inches and the bottom surface has a width between 9.25 inches and 9 inches. Embodiments of the present invention provide for a very thin housing. For example, the housing is no more than 0.19 inches thick. Embodiments of the present invention provide for a beveling of edges of the housing which is 2 millimeters or less thick. Embodiments of the present invention provide for a bent, polymer, rolled, or other type of compacting of the housing. Embodiments of the present invention provide for a heavy-weight. For example, the housing is weighted by its material and/or a weighting implementation in order to achieve a weight that is conducive to a specific user's needs. For example, for child-aged use, the weight is arranged to be about 1 pound to 2 pounds. For example, for adult-aged use, the weight is arranged to be 1.25 pounds to 4 pounds. Embodiments of the present invention provide for the weight to be positioned off center so that the center of mass of the housing is disposed in a location where a user will hold the device in the user's hand(s). Embodiments of the present invention provide for a gray or slate or a Kyoto wood colored housing. Other color and material combinations are contemplated and discussed above. Embodiments of the present invention provide for the housing to be composed of at least one of processed aluminum (e.g., anodized, et al.), wood (e.g., Kyoto wood, pressure-treated wood, light wood, waterproof wood). Embodiments of the present invention provide for cameras to reside and function in and/or on top of the housing.

Embodiments allow for interaction with a user by providing a housing to hold and/or display a display device, a cathode ray tube (CRT) monitor, a liquid crystal display (LCD) monitor, a light emitting diode (LED) monitor, a touchscreen, a flexible screen, etc.

The descriptions and illustrations of the embodiments above should be read as exemplary and not limiting. For example, different parts of the above described embodiments can be used with and without each other in various combinations. Modifications and/or variations are possible in light of the teachings above and the claims below, and are intended to be within the spirit and scope of the invention. Modifications and/or variations within the scope and spirit of the invention will be apparent to those of ordinary skill in the art.

What is claimed is:

1. A handheld computing device, the device comprising:
a rectangular casing, wherein at least two sides of the casing are beveled and the casing is made from a flexible material; and
a touch sensitive screen.

2. The handheld computing device of claim 1, wherein short sides of the casing are beveled inward towards the bottom of the device.

3. The handheld computing device of claim 1, wherein long sides of the casing are beveled inward towards the bottom of the device.

4. The handheld computing device of claim 1, wherein short sides of the casing are beveled inward towards the top of the device.

5. The handheld computing device of claim 1, wherein long sides of the casing are beveled inward towards the top of the device.

6. The handheld computing device of claim 1, wherein all four sides of the casing are beveled.

7. The handheld computing device of claim 1, wherein the at least two sides of the casing are beveled by 2 mm.

8. The handheld computing device of claim 1, wherein the flexible material is a bendable polymer.

9. The handheld computing device of claim 1, wherein the flexible material is wood based.

10. The handheld computing device of claim 1, wherein the touch sensitive screen is a capacitive screen for receiving input.

11. The handheld computing device of claim 1, wherein the touch sensitive screen is a resistive screen for receiving input.

12. The handheld computing device of claim 1, wherein the touch sensitive screen is both a capacitive screen and resistive screen for receiving input.

13. A computer tablet system, comprising:
a display screen; and
a rectangular housing, wherein the housing is made from a flexible material;
wherein the screen is coupled to housing.

14. The computer tablet system of claim 13, wherein at least two sides of the housing are beveled.

15. The computer tablet system of claim 14, wherein the at least two sides of the housing are at least one of: beveled straight inward toward the top of the computer tablet system, beveled straight inward toward the bottom of the computer tablet system, rounded inward toward the top of the computer tablet system, and rounded inward toward the bottom of the computer tablet system.

16. The computer tablet system of claim 13, wherein the respective corners of the housing are at least one of: square, rounded, and beveled.

17. The computer tablet system of claim 13, wherein the housing is made from a material selected from at least one of: plastic, hardgrade plastic, rubber, metal, tin, carbon fiber, titanium, wood, processed aluminum, bendable polymer, and pressure treated wood.

18. The computer tablet system of claim 13, wherein the housing is at least one of: smooth, rough, lightly variegated, heavily variegated, wavy, and includes indentations for finger grips.

19. The computer tablet system of claim 13, wherein the housing is coupled to the screen via at least one of: a hinge, a snap, a clip, a band, an adhesive, a removably-attached adhesive, and a magnetic apparatus.
